(19) United States
(12) Patent Application Publication
(10) Pub. No.: US 2008/0272408 A1
(43) Pub. Date: Nov. 6, 2008

(54) ACTIVE AREA JUNCTION ISOLATION STRUCTURE AND JUNCTION ISOLATED TRANSISTORS INCLUDING IGFET, JFET AND MOS TRANSISTORS AND METHOD FOR MAKING

(75) Inventor: Madhukar B. Vora, Los Gatos, CA (US)

Correspondence Address: PERKINS COIE LLP, P.O. BOX 1208, SEATTLE, WA, 98111-1208, US

(73) Assignee: DSM SOLUTIONS, INC., Los Gatos, CA (US)

(21) Appl. No.: 12/113,100

(22) Filed: Apr. 30, 2008

Related U.S. Application Data
(60) Provisional application No. 60/927,182, filed on May 1, 2007.

(51) Int. Cl. H01L 29/78; H01L 21/337; H01L 21/8236; H01L 21/44

(52) U.S. Cl. 257/272; 438/186; 438/276; 438/653; 257/E29.265; 257/E21.061; 257/E21.4

(57) ABSTRACT

Integrated active area isolation structure for transistor to replace larger and more expensive Shallow Trench Isolation or field oxide to isolate transistors. Multiple well implant is formed with PN junctions between wells and with surface contacts to substrate and wells so bias voltages applied to reverse bias PN junctions to isolate active areas. Insulating layer is formed on top surface of substrate and interconnect channels are etched in insulating layer which do not go down to the semiconductor substrate. Contact openings for surface contacts to wells and substrate are etched in insulating layer down to semiconductor layer. Doped silicon or metal is formed in contact openings for surface contacts and to form interconnects in channels. Silicide may be formed on top of polycrystalline silicon contacts and interconnect lines to lower resistivity. Any JFET or MOS transistor may be integrated into the resulting junction isolated active area.

### CROSS-REFERENCE TO RELATED APPLICATIONS

This application is related to and claims the benefit of priority under at least one of 35 U.S.C. § 119 and 35 U.S.C. § 120 to U.S. Provisional Patent Application No. 60/927,182 filed May 1, 2007 (Attorney Docket No. DSM-037 PA) entitled Junction Isolated IGFET and JFET and MOS Transistor Structures, which application is hereby incorporated by reference herein.

### FIELD OF INVENTION

This invention pertains generally to semiconductors that include transistor devices and structures for isolating the transistors from other transistors or from surrounding areas, and more particularly to an active area isolation structure and a semiconductor device that includes such active area isolation structure and a transistor device disposed within the active area isolation structure which may be an IGFET, JFET, MOS or other transistor, and to processes and methods for making these devices and structures.

### BACKGROUND

In the early days of bipolar transistor integration, aluminum contact wires were used. They ran across fields of silicon dioxide which were deposited on the surface of the substrate and then dipped down into contact holes for emitter, base and collector. Since the silicon dioxide layer was about 5000 angstroms (Å) thick, step coverage was a problem because the aluminum often would break down at the step and cause an open circuit. Isolation between active areas was accomplished by the diffusing into the substrate wells of impurities of the opposite type from the substrate. These diffusions created PN junctions which could be reverse biased. Basically, P-type isolation diffusions were made into N-epitaxial layers grown on the substrate to create PN junctions at the walls of the active areas between the P-type diffusion and the N-type epitaxial silicon.

FIG. 1A is a cross-section through the wafer after formation of N+ buried layers 10 and 12 and an N-type epitaxial silicon layer 14 grown on top of a P-type substrate 16. A thick silicon dioxide layer 18 was grown on top of the epitaxial layer. FIG. 1B shows a cross-section of the structure after the P-type isolation diffusions 20, 22 and 24 are performed to create N-type islands 14A and 14B in the epitaxial layer. These isolation diffusions created N-type islands of N-epitaxial silicon which were isolated from the substrate and each other by reverse biased PN junction diodes 26 and 28, as shown in FIG. 1C. Hamilton and Howard, Basic Integrated Circuit Engineering, FIG. 1-6, p. 13 (McGraw Hill 1975—hereafter, just “Hamilton”).

The conventional isolation diffusion to create active areas isolated by reverse-biased PN junctions had several problems, among them: (1) the time required for the isolation diffusion was considerably longer than any other diffusions because the diffusion or diffused material had to go vertically all the way down through the epitaxial layer; (2) because lateral or horizontal diffusion was great during the long isolation diffusions, considerable clearance had to be used or reserved for the isolation regions, and because those isolation diffusions occur at the perimeter of the device, considerable chip area was wasted, which cut down on device density and device count; and (3) the relatively deep sidewalls and large area of isolation regions contributed significant parasitic capacitance, which degrades device and circuit performance.

In response to those problems, several isolation methods were developed which avoided the use of the PN junction isolation diffusion but which had other problems and limitations. One of these was the Fairchild Isoplanar II process which is described in Hamilton, pp. 83-84 and in Hamilton FIG. 3-1. This process required growing of an N-epitaxial layer (hereafter just “epi”) on a P-substrate (the N and P polarities can be reversed) and etching of isolation trenches in the epi layer. Silicon dioxide was then thermally grown in the isolation trenches to isolate active areas in the epi layer between the silicon dioxide trenches. A layer of insulating material with a contact hole in it over the active area was used to allow an emitter contact to be made and a base contact was made at the edge of this layer of insulating material.

This Isoplanar II process still had step coverage issues for the emitter and base contact “wires”. This led to the Shallow Trench Isolation (hereafter sometimes referred to as STI) method of isolating active areas as device geometry continued to shrink. STI was developed because the step coverage issue became more of a problem at the smaller geometry sizes. Shallow Trench Isolation was more planar and at least partially eliminated step coverage issues.

By way of example, the STI process may typically involve the following process steps: (1) oxidation, (2) deposition, (3) lithography, (4) etch, (5) a cleaning process, (6) fill, and (7) chemical mechanical planarization (or polishing). Forming Shallow Trench Isolation (STI) areas around each device on an integrated circuit typically accounts for about one-third of the total fabrication cost of the chip. Elimination of the STI structure and process steps would simplify the chip fabrication process and associated fabrication costs. Elimination of the STI area would also make the total chip area consumed by each device less, so more complicated circuits with more transistors could be put on the same size die. Generally, yield is proportional to die size: the bigger the die, the lower the yield. Being able to put a circuit on a smaller die by virtue of elimination of the STI isolation means the yield will go up and the cost per chip will go down. Likewise, elimination of STI would make it possible to put more complicated circuits with more transistors on smaller dies than previously was possible so the cost per circuit goes down with the increasing yields.

Another reason why STI was added to integrated circuit structures in general was to prevent transistor latching, such as a SCR-like latching. In an integrated circuit structure comprised of an N-channel JFET adjacent to a P-channel JFET without STI isolation layers present between them, SCR-like latching can occur in any integrated circuit transistor structure, if four different semiconductor layers are joined together without interruption so as to form a PNPN (or an NPNP) structure. The SCR-like latching can occur if the voltage drop from the P structure to the final N structure in a PNPN concatenation exceeds one diode drop, (i.e., approximately 0.7 volts for Silicon-based structures and approximately 0.3 volts for Germanium-based structures).

FIG. 2 illustrates the SCR PNPN structure (which can alternatively be an NPNP structure) which can occur between any of several points in many MOS, JFET, and CMOS structures if the active areas are not electrically isolated from each other. Points A and B in FIG. 2 represent the terminals of the device. Latch-up can occur if the bias voltage across any one of these PNPN or NPNP structures between points A and B exceeds one diode junction voltage drop of a forward biased diode junction, (i.e., approximately 0.7 volts for silicon based devices and approximately 0.3 volts for germanium based devices) and certain conditions for the charge in the two bases (the innermost two layers) are right. STI prevents these charge conditions from occurring by electrically isolating neighboring active areas from each other and therefore prevents latch-up. But if no STI active area isolation is present, then these charge and voltage conditions can exist, and unwanted latch-up can occur thereby rendering the device inoperative.

Any CMOS, JFET, MOS, MESFET structure will have a four layer PNPN structure in it somewhere within it if STI or field oxide or some other form of electrical isolation is not present. An example is where there exist side-by-side two neighboring transistors which are not electrically isolated from each other.

If one were to plot the electrical current from point A to point B as a function of voltage for the structure of FIG. 2, a characteristic curve at least somewhat like that shown in FIG. 3 would be found to exist. The voltage at the breakpoint C in the curve is always one forward biased diode junction drop, which, in silicon, is about 0.7 volts. This phenomenon is called latching, and it destroys the operability of the device for its intended function.

It would be desirable to eliminate the cost and complexity of forming STI isolation in any CMOS, MOS, or JFET device or circuit, but the SCR-like latching problem has to be dealt with if the STI isolation is eliminated.

Another problem that would have to be dealt with if STI or field oxide or some other form of electrical isolation is not present. That problem is how to make interconnecting conductive lines between transistor terminals in neighboring active areas if there is no STI or field oxide at the surface of the substrate to insulate such a conductor or conducting lines from the semiconductor of the substrate. It very often happens that it is necessary to connect one or more terminals of a transistor to one or more terminals of a neighboring transistor.

FIG. 4 is an illustrative example of this potential interconnect line shorting situation. FIG. 4 is a partial schematic diagram of a NMOS saturated load digital inverter having two MOS transistors showing how the source 31 of the NMOS load device nMOS1 30 is connected to the drain 32 of nMOS2 drive transistor 34. Sometimes this connection between the source 31 and the drain 32 of transistors in adjacent active areas is implemented by extending the polycrystalline silicon or metal of the source contact 31 of the N-channel transistor 30 to join the polycrystalline silicon or metal of the drain contact 32 of the N-channel transistor 34.

A need has therefore arisen for a new semiconductor structure which eliminates STI without creating a latching problem, and which also eliminates the problem of shorting signals on interconnect lines to ground.

### SUMMARY

In one aspect, embodiments provide an active area junction isolation structure and junction isolated transistors including for example any of IGFET, JFET, and MOS transistors as well as a method for making these structures and transistors.

In another aspect, embodiments provide a device comprising: a semiconductor substrate doped to a first conductivity type; a first well formed within the substrate and doped to a second conductivity type; a second well formed within the first well and doped to a first conductivity type, the second well defining an active area; and separate electrically conductive surface contacts including a first electrical contact to the first well, a second electrical contact the second well, and a third electrical contact to the substrate, such that predetermined voltages can be applied to the contact of the first well and to the contact of the second well so that a junction between the first and second wells forms a reverse-biased diode, thereby electrically isolating the second well from the first well and the substrate.

In another aspect, embodiments provide a process sequence to make a semiconductor device, the process sequence comprising: growing an insulator layer on top of a substrate having a semiconductor layer which is doped to a first conductivity type; masking to expose a first area where a first well of a second conductivity type is to be formed and implanting second conductivity type impurities into the semiconductor layer to form a first well; masking to expose a second area where a second well of a first conductivity type is to be formed and implanting first conductivity type impurities to form a second well inside the first well; masking to define an active area and etching through the insulating layer to expose the top surface of the semiconductor layer; forming contact holes in the insulating layer to expose portions of the top surface of the substrate where electrical contact may be made to the substrate, the first well and the second well, and forming an opening in the insulating layer to expose an active area; and forming surface contacts in the contact holes making electrical contact with the substrate, the first well and the second well.

In yet another aspect, embodiments provide a method for forming an interconnect conductor between nodes in an integrated circuit having no Shallow Trench Isolation or field oxide between active areas of transistors comprising the steps: depositing a layer of insulating material on the surface of a semiconductor layer of a substrate, wherein the insulating layer is comprised of a first layer of silicon dioxide, an intermediate layer of silicon nitride, and a top layer of silicon dioxide; etching a contact opening in the layer of insulating material all the way down to a top surface of the semiconductor layer; etching at least one interconnect channel down through the top layer of silicon dioxide to a top of the silicon nitride layer, the trench interconnecting with the contact opening; depositing a layer of titanium or other metal suitable to form a silicide over the entire structure so as to form a lining for the contact opening and the interconnect channel; baking the structure so as to form a silicide ohmic contact in the bottom of the contact opening; etching off excess titanium or other suitable metal for forming the silicide which has not formed silicide; depositing a layer of titanium or other suitable metal so as to line the contact opening and the interconnect channel; depositing a layer of tungsten or other spiking barrier metal on top of the layer of titanium; depositing a layer of aluminum so as to fill the contact opening and the interconnect channel; and polishing the aluminum in the contact opening and the interconnect channel down so as to be flush with the top surface of the top layer of silicon dioxide.

In even another aspect, embodiments provide an interconnect conductor formed between nodes in an integrated circuit having no Shallow Trench Isolation (STI) or field oxide between active areas of transistors.

In still another aspect, embodiments provide an integrated transistor comprising: a semiconductor substrate doped to a first conductivity type and having a top surface upon which is formed a multi-layer insulation layer comprised of a first insulator, a second polish stop insulating layer on top of the first insulator, the polish stop insulating layer capable of stopping a polishing process, and a third insulating layer formed on top of the etch-stop insulating layer; a first well formed in the substrate and doped to a second conductivity type; a second well formed in the first well and doped to a first conductivity type, the second well defining an active area; a dielectric layer covering the top surface of the substrate and having contact holes formed therein which expose areas of the substrate where electrical contact can be made to the substrate, the first well and the second well and having a hole therein exposing an active area portion of the substrate within a perimeter defined by the intersection of the second well with a top surface of the substrate; separate electrically conductive surface contacts in the contact holes making electrical contact to the substrate, the first well and the second well; and any transistor structure formed in the active area.

Other aspects will be apparent from the detailed description and accompanying drawings.

### BRIEF DESCRIPTION OF THE DRAWINGS

FIG. 1 including FIGS. 1A, 1B, and 1C illustrate aspects of conventional isolation structures, circuits, and methods for creating electrically isolated active areas of semiconductor in an epitaxial silicon layer, where FIG. 1A illustrates the structure before the P-type isolation diffusion, FIG. 1B illustrates the structure in cross-section after the P-type isolation diffusion, and FIG. 1C illustrates the reverse-biased diode isolation of each active area defined by the P-type isolation diffusion from the substrate.

FIG. 2 is a diagram of a four layer SCR semiconductor structure which will latch if the bias across the four layers from points A to B exceeds a certain voltage.

FIG. 3 is a characteristic curve of current versus voltage which is typical of the latching phenomenon in any PNPN structure of an integrated circuit such as the one in FIG. 2.

FIG. 4 is a partial schematic diagram of a NMOS saturated load inverter showing how the source of the NMOS load device nMOS1 is connected to the drain of nMOS2 drive transistor.

FIG. 5 is a plan view showing how in the polycrystalline silicon or metal source contact of an nMOS1 transistor can be extended across the open area of substrate from the active area the nMOS transistor to join the drain contact of the nMOS2 transistor over its active area.

FIG. 6 is a cross-sectional view along section line 8-8′ in FIG. 5 showing how an interconnect extends from one active area to the other across the intervening STI or field oxide.

FIG. 7 is a cross-section through the an exemplary embodiment of an active area isolation structure (AAIS) showing the location of a junction isolated active area (within the P-well) where any semiconductor circuit element such as a transistor may be formed.

FIG. 8 is a cross section through the active area isolation structure showing formed in the active area the structure of an N-channel junction field effect transistor.

FIG. 9 is a circuit diagram of an exemplary JFET inverter.

FIG. 10 is a doping profile diagram of an exemplary n-channel JFET.

FIG. 11 is a cross-sectional view of an embodiment of a JFET with metal source, drain and gate electrodes formed using the active area isolation structure of FIG. 7.

FIG. 12 is a cross-sectional view through an interconnect structure which is equally applicable to the embodiments disclosed herein.

FIGS. 13A-13D show a cross-section through an exemplary NMOS transistor device after the first few steps to form the N-well implant of the new isolation structure.

FIGS. 14A-14D are views including a cross-section through the active area (the P-well of FIG. 14A) of and cross sections along section line B-B′ (FIG. 14B) and section line C-C′ (FIG. 14C) after the first few steps to form the N-well implant and the P-well implant of the exemplary NMOS transistor device.

FIGS. 15A-15D are views including a cross-section through the active area (FIG. 15A) of and cross sections along section line B-B′ (FIG. 15B) and section line C-C′ (FIG. 15C) of JFET isolation structure without STI isolation after the first few steps to form the N-well implant and the P-well implant of the exemplary NMOS transistor device. FIG. 15D is a plan view of the structure.

FIG. 16 depicts a finished NMOS transistor device implemented in the manner of embodiments of the invention without the use or presence of a Shallow Trench Isolation (STI) structure.

FIG. 17 shows a second embodiment of an NMOS device, using the isolation structure described herein with a polysilicon gate surface contact with no spacers and silicide source and drain surface contacts.

FIG. 18 is a cross-sectional view of another embodiment of an MOS transistor using the non-STI active area isolation structure (AAIS), in which a polysilicon gate surface contact is used. Here, the contact has a silicide cap and a spacer dielectric insulating the vertical side walls of the gate surface contact.

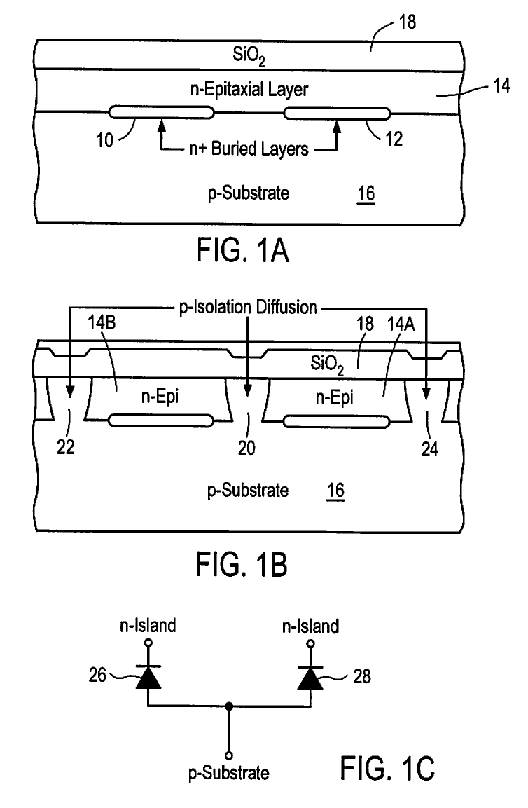

### DETAILED DESCRIPTION OF EXEMPLARY EMBODIMENTS

Although Shallow Trench Isolation (STI) structures and methods may still have applicability, the afore-described problems and limitations associated with the use of Shallow Trench Isolation (STI) and/or other field oxide have been solved and overcome by embodiments of the present invention that provides an alternative structure and method that provide junction isolation such as in the form of an active area isolation structure (AAIS) within a semiconductor structure and device

The various embodiments disclosed herein teach a method and device structure to build a variety of semiconductor or transistor structures, including any Metal Oxide Semiconductor (MOS), or Junction Field Effect Transistor (JFET), or Insulated Gate Field Effect Transistor (IGFET) structure using junction isolation only without Shallow Trench Isolation (STI). In one embodiment, the junction isolation is referred to as active area isolation structure (AAIS). Also disclosed is a novel method of forming electrically conductive interconnections (interconnects) between device terminals in neighboring active areas when no STI or field oxide is present isolating the neighboring active areas.

Non-limiting embodiments form, provide, and use a novel and unique junction isolation or active area isolation structure (AAIS) comprised of a double-well implant isolation structure. Other embodiments may also provide an additional isolation and are referred to as triple-well isolation structures.

Headers and subheaders if present in this description are provided for the convenience of the reader should not be interpreted to limit the scope of the invention in any way. Various aspects and features of different embodiments of the invention are described throughout the specification and are not limited to particular sections.

In one embodiment, the double-well isolation structure comprises an N-well formed in a P-doped substrate with a P-well formed inside the N-well. Advantageously, surface contacts to the P-doped substrate, the P-well, and the N-well are formed so that voltage conditions can be controlled to form reverse-biased PN-junctions such as the junction between the P-well and the N-well so as to isolate the active area (within the P-well) from adjacent active areas. Inside the P-well, any NMOS, PMOS, N-channel JFET, P-channel JFET structure, or other transistor or other semiconductor device or structure can be formed. All of the above teachings and innovations are applicable if the polarities of the devices are reversed, for example, an N-substrate, a first P-well and the active area being an N-well formed inside the P-well.

It may be appreciated in light of the description provided here, that elimination of Shallow Trench Isolation (STI) would conventionally cause polycrystalline silicon or metal interconnects running across an expanse of substrate between active areas to be shorted to the conductive substrate. Conventionally, elimination of STI or field oxide isolation might also be expected to create the possibility of an SCR-like latching problem in any NPNP or PNPN structure in the device. An NPNP or PNPN structure may conventionally latch if charge conditions are right for such latching and the total voltage drop from the first N-layer to the last P-layer in an NPNP structure or from the first P-layer to the last N-layer in a PNPN structure exceeds one forward biased PN (or NP) junction drop. It is therefore generally observed to restrict the operating voltage of any device constructed according to the at least some exemplary embodiments so as to not exceed one forward biased PN junction drop, (i.e., approximately 0.7 volts for Silicon based devices or approximately 0.3 volts for Germanium based devices), along any NPNP (or PNPN) path to prevent the latching problem known in the conventional art.

Elimination of STI or field oxide is implemented without losing isolation of one active area from another by adding a surface contact to the substrate that surrounds the P-well and N-well and providing a surface contact to P-well and N-well so that the N-well to P-substrate PN junction can be reverse biased in each device to electrically isolate each device from the others formed in the same substrate.

In several non-limiting exemplary embodiments, the gate operating voltage is restricted to substantially 0.5 volts to ensure no latching in any PNPN (or NPNP) structure which may be formed will occur such as the path from the P-type gate region to the N-type channel region to the underlying P-well to the underlying N-well. If the gate voltage were not limited to less than one forward biased diode drop, then this PNPN current path could latch like an SCR.

The elimination or omission of STI can be applied to any integrated semiconductor structure in the MOS or JFET families, MOS and JFET devices are operated usually with the gate voltages restricted to less than approximately 0.7 volts for Silicon based devices or approximately 0.3 volts for Germanium based devices, if the devices will work at that voltage.

Embodiments also provide a new method of fabrication of polycrystalline silicon interconnect wires or other electrical connections and a new resulting device structure. This new method of fabrication and resulting device structure is made necessary the need for replacement of an isolation structure resulting from the elimination of the STI insulation between active areas, and the addition of the insulating layer (or a sandwich of multiple insulating layers or materials is featured in some of the embodiments) on top of the substrate outside the active area and covering the active area except in the location of contact openings down to the surface of the active area.

It may be appreciated in light of the description provided herein that in the conventional devices, STI insulation material was formed in the substrate and typically came up to the surface of the substrate between active areas of devices that needed to be interconnected. For example, in a JFET inverter, the source of the P-channel JFET needs to be interconnected to the drain of an N-channel JFET. In conventional devices, this could be done by extending the drain contact polycrystalline silicon of the N-channel JFET outside the N-channel active area and across the STI field to join with an extension of the source contact polycrystalline silicon of the P-channel JFET. In cross-section, this prior art polycrystalline silicon wire or electrical connection or interconnect has a uniform thickness all the way from the P-channel device to the N-channel device. However, when the STI is eliminated, this structure cannot be used because the polycrystalline silicon interconnect device will be in electrical contact with the top of the conductive substrate. Since the source and drain and gate contact polycrystalline silicon or metal interconnect wires all run across what in the heretofore conventional devices formerly were the STI insulation field, the electrical contact between these wires and the conductive substrate short circuits or shorts them out and eliminates the ability to apply different bias voltages to the source, drain, and gate of the JFET thereby rendering it inoperative.

In the innovative structures describe herein, to prevent this undesirable result, a layer of insulation is deposited on top of the substrate between devices that need to be or may need to be interconnected by polycrystalline silicon extensions of the source, drain, or gate lines contact structures. This insulating material deposited on top of the substrate performs the insulating function of the STI in the conventional structure. Advantageously, in at least some non-limiting embodiments, polycrystalline silicon (or metal) as described in greater detail herein, is then deposited in the contact holes and over the top of the insulating layer on top of the substrate and etched to form the desired interconnect wire or other electrical connections, and then is polished back so as to have a flat top surface. The idea is to eliminate step coverage issues for certain structures, such as for example for metal interconnects, that need to pass over the polycrystalline silicon interconnects. The polycrystalline silicon itself of the gate contact and its extension as an interconnect wire or connecting member is deposited into the gate contact hole and makes contact with the active area. Outside the active area, an insulator material or materials, such as a layer of silicon dioxide, silicon nitride, and more silicon dioxide, is used to insulate the source, gate, and drain interconnect wires from making electrical contact with the substrate outside the active area or the active areas of neighboring devices.

The polycrystalline silicon interconnect wires or connecting member may have greater thickness in the contact holes than outside them. This might normally be expected to lead to a top surface of the polycrystalline silicon interconnect wire or other electrically conductive trace 13- or material having an uneven quality because it might conventionally dip down in the area where the contact hole was located. This dip would be mirrored in the top surface of any insulating layer deposited over the polycrystalline silicon interconnect wire or other electrical connection. This would normally create a step coverage issue for structures such that metal interconnect lines that are deposited on top of the insulating layer over the polycrystalline silicon interconnect. However, in the structures according to non-limiting exemplary embodiments, a chemical-mechanical polishing (CMP) step is used to polish the tops of the polycrystalline silicon interconnect wires or other interconnections back to flush with the top surface of the top layer of silicon dioxide in an oxide-nitride-oxide insulating multi-layer or layer sandwich structure. This multi-layer or sandwich insulating structure defines the active areas and covers the fields of substrate between devices. Because the top surfaces of these polycrystalline silicon interconnect wires is flat or substantially flat after the polishing step, there is no step coverage issue even though STI has been eliminated.

Aspects and embodiments of the present invention are now described in additional detail relative to the accompanying drawings.

As was described relative to FIG. 4 in the background, conventional structures may present an electrical shorting problem when STI or field oxide or some other form of electrical isolation is not present.

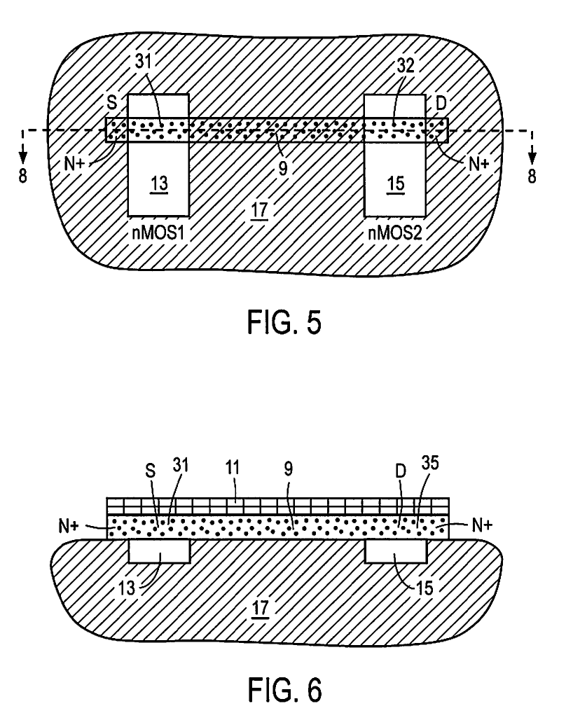

With reference to FIG. 5, there is shown a plan view illustrating how in the polycrystalline silicon or metal source contact 31 of an nMOS1 transistor 30 can be extended across the open area 17 of a substrate from the active area 13 of the nMOS transistor 30 to join the drain contact 32 of the nMOS2 transistor 34 over its active area 15. The presence of STI or field oxide in this structure serves to isolate active areas 13 and 15 of neighboring NMOS devices and eliminates short circuiting the conductor 31, 32 to the substrate, which would tie the source and drain voltages of nMOS1 and nMOS2 to the substrate voltage.

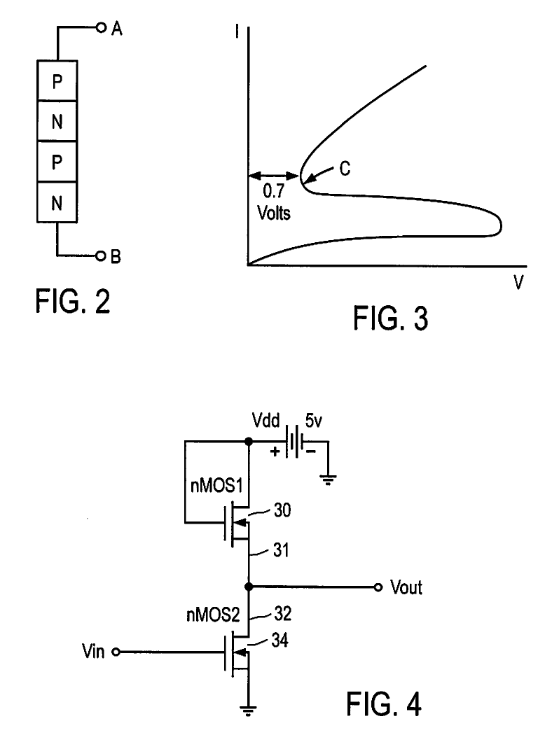

A similar situation arises in CMOS inverters where the drains and gates of the adjoining NMOS and PMOS transistors may need to be connected together so there will be two polycrystalline silicon or metal interconnections that connect the gates of adjoining PMOS and NMOS devices together and the drains of adjoining PMOS and NMOS devices together. In absence of STI structure, the gates of the PMOS and NMOS devices will be shorted to the substrate. The presence of the STI or field oxide also eliminates the possible latching problem illustrated in FIG. 2 and FIG. 3.

FIG. 6 is a cross-sectional view of the interconnect of FIG. 5 showing how a polycrystalline silicon interconnect 9 between the source and drain of adjoining NMOS transistors runs across the insulated surface of the substrate provided by STI or field oxide 17 which fills the space in the substrate between the active areas 13 and 15 of the adjoining transistors. Because of the presence of this STI or field oxide, the interconnect 9 is insulated from the voltage source coupled to the substrate, and the devices work properly. Polycrystalline silicon interconnect 9 is shown as having a layer of silicide 11 on top thereof to reduce the resistivity of the polysilicon. Because the surface of the substrate between the active areas 13 and 15 is non-conductive, the polycrystalline silicon interconnect 9 can run directly across the surface of the substrate without being shorted out to the substrate or shorting out any PN junctions which might otherwise be present at the surface of the substrate. If STI is eliminated, this insulation or isolation attribute is not present, and absent some other attribute to overcome this lack of insulation or isolation, failure of the device of the structure of FIG. 6 would occur because the semiconductor substrate is conductive and would cause leakage to ground from the interconnect 9 or shorting to ground of the signals on such interconnect line 9 and application of the substrate voltage to the source of nMOS1 and to the drain of nMOS2 in FIG. 4.

Attention is now directed to an embodiment of the invention that provides an active area isolation structure and method of forming the structure, that replaces and eliminates the need for a Shallow Trench Isolation (STI) structure and its associated method of manufacture and also eliminates the problems and limitations associated with conventional isolation structures and methods, including eliminating STI without creating a latching problem, and which also eliminates the problem of shorting signals on interconnect lines to ground. Other advantages and benefits will be apparent from the description provided.

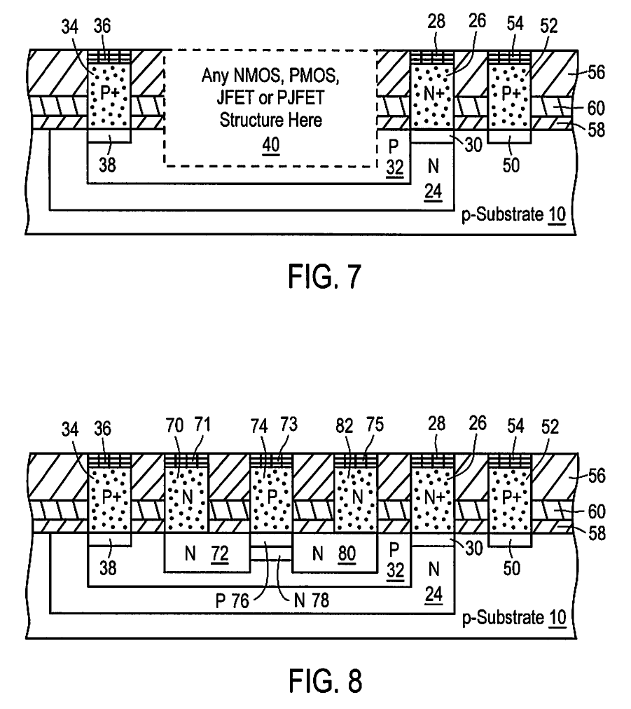

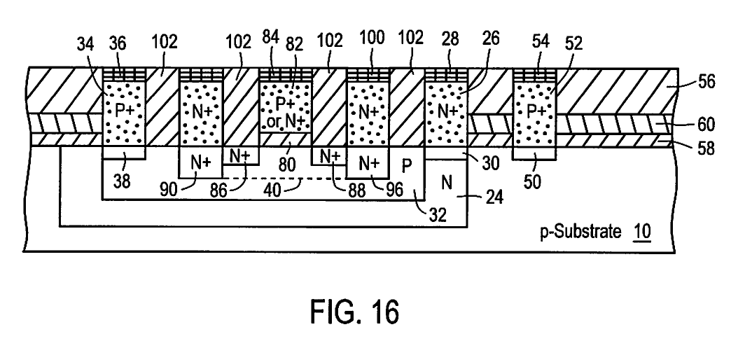

With reference to FIG. 7, there is illustrated a cross-sectional view through the generic inventive active area isolation structure (AAIS) showing the location of a junction isolated active area 40 (within the P-well 32). The active area isolation structure (AAIS) is referred to herein as generic at least because of its applicability for isolating an extremely broad range of semiconductor device types including isolating any diode device, any transistor device, or any device no matter how many terminals that is formed in a semiconductor material independent of its device name or number of terminals. Such any transistor includes but is not limited to a transistor selected from the group of transistors that include NMOS transistors, PMOS transistors, Insulated-Gate Field Effect Transistor (IGFET) transistors, N-channel Junction Field Effect (JFET) transistors, and P-channel JFET transistors, may be formed in the region 40 location on FIG. 7 designated for the transistor structure. Note that NMOS and PMOS devices will generally work if a semiconductor for the substrate is used with a work function which is such that the threshold voltage of the MOS device is less than about 0.5 volts because the Vdd power supply voltage is limited in most embodiments to about 0.5 volts in these non-STI embodiments to prevent latching. As noted below, the examples shown in FIGS. 8-15 show the novel isolation structure using a JFET as the transistor structure. FIG. 16 et seq. illustrate exemplary transistor structures, including but not limited to MOS transistor structures, built inside the novel isolation structure 40.

A triple-well and reverse-biased PN junction isolation structure and method is used instead of field oxide or Shallow Trench Isolation to isolate the active area. With reference to the structure shown in FIG. 7, an N-doped well 24 is formed in the P-substrate 10 and is in electrical contact with an ohmic contact 30 which is in electrical contact with an N+ doped polycrystalline silicon surface contact 26 which has a layer of titanium silicide 28 on top thereof. A P-doped well 32 formed inside the N-well 24 forms the electrically isolated active area in which the transistor may be formed. The P-well 32 is in electrical contact with an ohmic contact 38 which is in electrical contact with a P+ doped polycrystalline silicon surface contact 34 which has a layer of titanium silicide 36 formed on top thereof.

A P-doped substrate 10 is in electrical contact with an ohmic contact 50 which is in electrical contact with a P+ doped polycrystalline silicon contact 52 which has a layer of titanium silicide 54 formed on the surface thereof.

All the ohmic contacts such as ohmic contact 50 are formed by diffusing impurities out of the overlying doped polycrystalline silicon surface contact. In the case of ohmic contact 50, impurities from the P+ doped polycrystalline silicon contact 52 are diffused into the underlying substrate. The same is true for ohmic contact 38.

The surface contacts 34, 26 and 52 can also be formed of metals such as aluminum, gold, silver, titanium, tungsten, and the like. If they are formed of any metal which has a spiking problem where metal atoms might diffuse into the underlying substrate, a titanium-tungsten silicide spiking barrier may be formed between the metal and the substrate to prevent spiking and a titanium silicide ohmic contact may be formed under the spiking barrier to make good electrical contact.

It may therefore be appreciated that according to different embodiments, polysilicon surface contacts as well as metal silicide contact may be used. Instead of polysilicon surface contacts to the substrate, N-well and P-well of the isolation structure, metal silicide contacts may be formed at the bottoms of contact holes etched down to the substrate surface at locations where the electrical contact can be made to the substrate, the N-well and the P-well. The term surface contact is intended to cover various types of surface contacts including both polysilicon and silicide electrical contacts to underlying substrate structures unless otherwise specifically limited to one type of surface contact.

Because the polycrystalline silicon or metal of the surface contacts must be insulated from each other, and because the contacts of any transistor built in the active area must be insulated from each other and usually must be extended outside the active area to make contact with contacts of other transistors terminals in other active areas, a layer of insulation must be deposited on the top surface of the substrate 10, 48. In the preferred embodiment, this layer of insulation is a multi-layer insulator with an etch-stop layer intermediate between inner and outer layers of the multi-layer or sandwich structure, such as in the middle thereof. A typical embodiment is comprised of a first layer of thermally grown silicon dioxide (hereafter sometimes referred to simply as oxide) 58 with an etch-stop layer of silicon nitride 60 formed on top of the thermal oxide. A thick layer of Chemical Vapor Deposition (CVD) deposited oxide is formed on top of the etch-stop layer. Any other material that can stop an etch of CVD oxide layer (or other material layer or an oxide layer formed other than by CVD) may also be used. Typical thickness for thermal oxide layer 58 is about 1000 angstroms (A). Typical thickness for the nitride layer 60 is about 200 A. Typical thickness for the CVD oxide insulating layer 56 is about 3000 A.

FIG. 8 is a cross section through the active area isolation structure 40 showing formed in the active area the structure of an N-channel junction field effect transistor (hereafter JFET). Drain current in a JFET is dependent upon a depletion region formed at the PN junction between the gate and the channel. The voltage at the gate with respect to the source controls the width of the depletion region of the gate-to-channel junction. The undepleted part of the channel is available for conduction. Thus, the channel is turned on and off by applying appropriate voltages at the gate and the source terminals of the JFET. Current will flow between the source and drain when the channel is turned on and the appropriate voltage is applied to the drain. As mentioned above, the JFET transistor structure will be used now to illustrate the isolation scheme.

One of the features that is new in the structure of FIG. 8 is that the JFET is built without any STI or field oxide to electrically isolate the active area. Since the JFET operates at a Vdd voltage of 0.5 volts to limit the gate current when the transistor is on, it works nicely in the non-STI isolation structure where Vdd must be limited to 0.5 volts to prevent the afore described latching problem that may occur at about 0.6 to 0.7 volts.

In FIG. 8, the JFET source contact 70 makes ohmic contact with a source region 72. Gate contact 74 makes ohmic contact with gate region 76 of a first conductivity type. The gate region 76 is typically very shallow and joins the channel region at a depth of only approximately 10 nanometers. The channel region is doped to a second conductivity type, and its doping profile in terms of concentration and depth is controlled to form the normally off JFET. Curve 86 in FIG. 10 is a typical doping profile for the normally off JFET channel region. Typical depth for the channel-well junction shown at 89 is only about 50 nanometers. The depths of the gate-channel junction 91 and the channel-well junction 89 and the doping concentration are controlled such that the depletion regions of the gate-channel junction 91 and the channel-well junction 89 touch so as to cause pinch off and no conduction when the voltage of the gate relative to the source is 0.0 volts. It is beneficial to keep the concentration of impurities in the gate region high (or even very high) and higher (even much higher) than the concentration of the impurities in the channel region. This ensures that most of the depletion region around the gate-channel PN junction is in the channel and not the gate (in order to achieve pinch-off). This is done for example, by keeping the gate-channel PN junction very shallow so the gate region is narrow (which effectively drives the concentration up). There is a problem with etching the polycrystalline silicon contacts 70, 74 and 82 in FIG. 8 because this etch must stop at the surface of the P-well 32 and not etch into the P-well; such etch overshoot could etch all the way through the thin gate region or could etch away the source and drain regions 72 and 80 past the depth of the gate-channel junction.

One of the discoveries associated with solving this etch overshoot problem is eliminating the etching into polysilicon for the contacts, which is so difficult to control. This conventional etching process and etch step is replaced with a novel approach and process with one that only etches contact openings into the insulating layer, rather than into the polysilicon. The multi-layer insulation layer comprised of thermally grown silicon dioxide 58, silicon nitride 60, and silicon dioxide 56 (advantageously deposited by chemical vapor deposition) is deposited on the surface of the P-well 32. Contact openings are then etched into this insulation layer, rather than into polysilicon. These contacts are not over the source and drain regions. The contact openings are filled with polycrystalline silicon and polished back to be flush with the top of layer 56. These polycrystalline silicon contacts can then be doped by ion implantation using suitable mask steps and impurities to arrive at the structure shown in FIG. 8. A layer of titanium silicide may be formed on top of each polycrystalline silicon electrode to enhance the conductivity of the doped polycrystalline silicon. Thermal drive-in of the impurities from the source, gate, and drain contacts formed in this manner may be used to form underlying, self-aligned source, gate, and drain regions, respectively, in the P-well 32.

The channel joins the source region 72 to the drain region 80 and conducts current there between when the transistor is turned on in the manner described below. The drain contact is shown at 82. The source, gate and drain contacts may be doped polycrystalline silicon or metal with suitable spiking barriers where necessary (such as where the metal is aluminum). For an n-channel JFET, the source and drain regions are doped n-type, the channel is n-type, the gate is p-type, the source and drain polycrystalline silicon contacts are doped n-type and the gate contact is doped p-type. The back gate contact is provided functionally by the P-well surface contact 34 in FIG. 8. Typically, the gate region is self-aligned and is formed by diffusing acceptor impurities from the heavily doped gate contact 74 into the underlying semiconductor to convert a portion of the channel 78 into a p-type gate regions 76, but ion implantation may also be used. The source, drain and channel regions are typically formed with one or more separate n-type impurity ion implantation steps.

The source, drain, and gate contacts are typically polycrystalline silicon doped to the appropriate conductivity type by one or more steps of ion implantation. However, they can also be doped by plasma immersion implantation or they can be metal, with suitable metal atom spiking barriers (typically titanium/tungsten where aluminum is the metal of the electrode) if necessary.

Self-aligned silicides 71, 73 and 75 are formed on top of polycrystalline silicon source, gate and drain electrodes, respectively, in the preferred embodiment of the species of FIG. 8.

In an alternative embodiment to that illustrated and described relative to the JFET structure within the active area isolation structure in FIG. 8, the portions of the JFET source and drain regions 72 and 80 between the gate region and the source and drain regions is formed by ion implantation, plasma immersion, or other similar doping methods.

In another alternative embodiment, an epitaxially grown layer of silicon-germanium semiconductor (not shown) is grown selectively only on the top surface of the P-well 32 before the multilayer insulation layered structure 58, 60, 56 is formed. The epitaxial layer is grown so as to underlie the source, gate, and drain electrodes, and the portion of the epitaxial semiconductor under the gate electrode is doped appropriately to form the channel and the gate regions.

More precisely, in one non-limiting embodiment, the structure of this alternative embodiment includes the following substructures: First, there are non-overlapping source and drain regions formed in the P-well so as to be adjacent to a top surface of the P-well and doped with conductivity enhancing N type impurities (or P type if a P channel device is being formed in which case the P-well will be an N-well); an epitaxially grown layer of silicon-germanium is formed only over the P-well; an electrically conductive gate electrode overlies the P-well between the source and drain regions and lies over said epitaxially grown layer of silicon-germanium; a gate region of P type impurities (or N type for a P channel device) is formed in said epitaxially grown layer of silicon-germanium under said gate electrode and between said source and drain regions; electrically conductive source and drain electrodes are formed on top of said epitaxially grown layer of silicon-germanium and overlying said source and drain regions, respectively so as to make electrical contact therewith through said epitaxially grown layer of silicon-germanium; and a channel region of N type conductivity is formed in said epitaxially grown layer of silicon-germanium and immediately underneath said gate region and between said source and drain regions.

In alternative embodiments, the channel region in this class of species can be formed in a strained silicon-germanium alloy, silicon-germanium-carbon alloys, or in other alloys. Doping of the epitaxially grown layer of semiconductor is typically by ion implantation but may also be by atomic layer epitaxy or similar techniques. Since the channel is in the epitaxial layer and mobility is much higher in this layer, high-frequency performance is better than in conventional structures.

Another alternative embodiment of the epitaxial layer embodiments just discussed is the use of silicon-carbide or silicon-germanium carbide to form the gate electrode 74. This increases the barrier height at the gate-channel junction in the epitaxially grown layer of semiconductor. This higher built-in potential at the gate-channel PN junction reduces the saturation current across the junction and allows an increase in the maximum voltage which can be applied to the gate-channel diode to forward bias it without causing a significant amount of gate current to flow across the junction. This allows a higher Vdd to be used to increase the drive strength of the transistors and increases switching speed. However, in order to prevent SCR-like latching, Vdd must not be raised above the threshold voltage above which such latching may occur, again about 0.6 to 0.7 volts for silicon based structures.

An exemplary but non-limiting process 100 to make an embodiment of the structure of FIG. 8 is now described, assuming an N-channel JFET, and with the understanding that the polarities described are reversed for P-channel JFETs. First (step 101), form the double well isolation structure of FIG. 7 (and, in some embodiments further grow an epitaxial layer of semiconductor over the P-well). Second (step 102), ion implant the channel region in the P-well (or in the optional grown epitaxial (epi) layer). Third (step 103), form an insulation layer over the P-well active area, such as the thermal oxide 58, silicon nitride 60, CVD oxide 56. Fourth (step 104), mask and etch contact openings for the source, drain, and gate electrodes. Fifth (step 105), deposit polycrystalline silicon to fill the openings (step 105A), polish back to the top of the insulation layer (step 105B), and selectively dope the polycrystalline silicon to form the source, gate and drain electrodes (step 105C). Sixth (step 106), diffuse impurities into the underlying semiconductor to form the source, gate and drain regions. Seventh (step 107), implant the linking regions between the source and drain regions and the gate region. Eighth (step 108), form silicide on top of the polycrystalline silicon source, drain, and gate electrodes. During this process, the doping profiles of the gate and channel and the doped region under the channel are controlled to achieve the desired type of enhancement mode or depletion mode JFET and the voltage at which pinch off occurs.

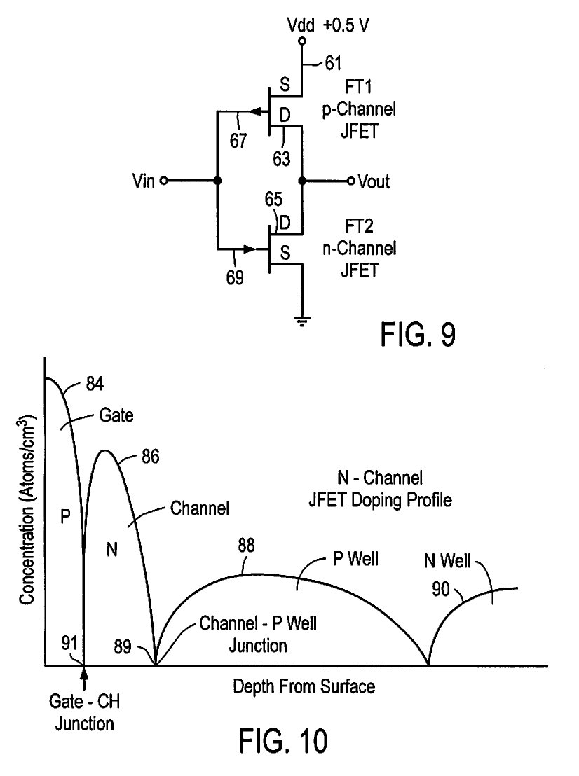

FIG. 9 is a circuit diagram of a JFET inverter which is similar to a CMOS inverter and which uses the transistor structure of the JFET. FIG. 9 will be used to illustrate characteristics of the JFET. The JFET transistors FT1 and FT2 in FIG. 9 operate in a manner similar to the MOS transistors of a CMOS inverter. The p-channel JFET FT1 is connected to the power supply Vdd at its source terminal 61. The drain terminals 63 and 65 of FT1 and FT2 (an n-channel JFET) are connected together and to the output voltage terminal Vout. The gate 67 of FT1 is coupled to the gate 69 of FT2 and to the input voltage terminal Vin.

The gate of the p-channel JFET FT1 is made of n-type silicon and the channel is doped p-type so there is a PN junction at this intersection, and it is the doping profile around this PN junction and the voltages applied to the gate relative to the source which control conduction in the JFET. The doping profile of the p-channel JFET FT1 is designed to turn off conduction through the channel when the voltage on the gate terminal is zero volts relative to the source. FT1 is therefore an enhancement mode device. The doping profile of an n-channel JFET is shown in FIG. 10. The profile is the same for p-channel JFETs but the polarities are reversed. Curve 84 is the gate doping profile starting from the silicon surface. Curve 86 is the channel doping profile, and curves 88 and 90 are the P-well 32 doping profile and the N-well 24 doping profiles, respectively.

The JFET inverter operates in a very similar manner with similar characteristics as a CMOS inverter built with today's line widths and gate dielectric thicknesses which are such as to not permit much gate leakage current. However, at least one advantage of the structure of FIG. 8 is that the approximately one third of the cost of building the structure which is attributable to formation of STI isolation has been eliminated from this structure.

The functioning of the JFET inverter is as follows. Vdd is fixed at 0.5 volts. When Vin is 0.5 volts, FT1 is off and FT2 is on. When Vin is 0.0 volts, FT1 is on and FT2 is off.

The bias voltages and polarities of the JFET conductive structures are opposite for the n-channel JFET.

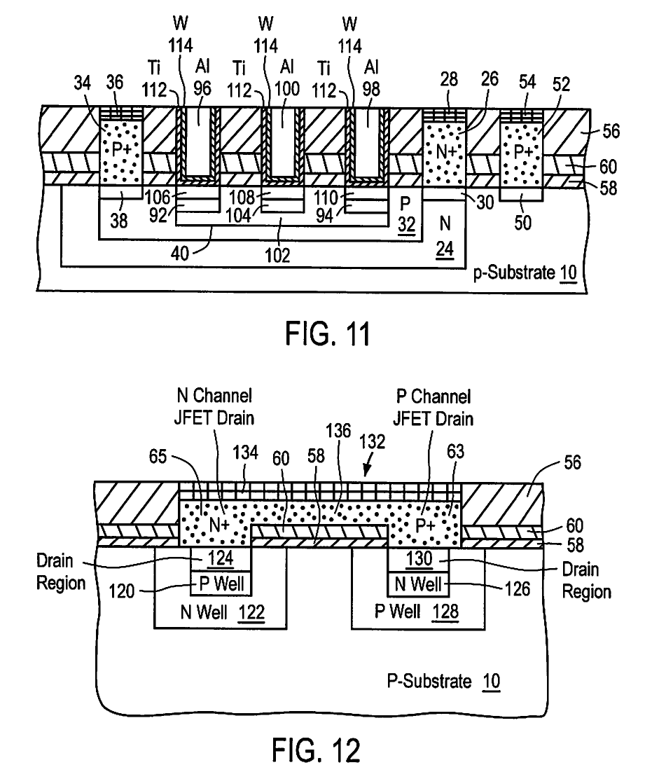

At very small geometries, such as for example 40 nanometers line width, it is difficult to form polycrystalline silicon contacts for the source, drain, and gate. This is because the contact holes are made at the minimum line width and small contact openings require thin layers of materials to fill them. Polycrystalline silicon is difficult to deposit in such a thin layer reliably. To solve this problem, metal can be used to form the source, drain, and gate electrodes. An example of such a structure is shown in FIG. 11.

FIG. 11 is a cross-sectional view of an embodiment of a JFET with metal source, drain and gate electrodes formed using the generic isolation structure of FIG. 7. Source region 92 and drain region 94 underlie metal source and drain contacts 96 and 98, respectively. In some embodiments using ion implantation to form the source and drain regions through the contact holes for the source and drain electrodes, these source and drain regions are self-aligned. The source and drain regions extend into but not through a channel region 102. A gate region 104 underlies a gate electrode 100. In some embodiments, the gate region is self-aligned and is formed by ion implantation through the gate electrode opening etched into the multi-layer insulation layer comprised of thermally grown silicon dioxide 58, silicon nitride 60, and CVD silicon dioxide 56. Each of the source, gate, and drain regions has an ohmic contact thereto shown at 106, 108 and 110, respectively.

Each of the source, gate and drain contacts is formed of aluminum with a titanium/tungsten spiking barrier comprised of a titanium layer 112 and a tungsten layer 114. These two layers are deposited to line the insides of the contact openings with the titanium layer being deposited first and baked at about 800 degrees C. for about 30 minutes so as to form titanium silicide ohmic contacts 106, 108 and 110. In some embodiments, a sputtered layer of polycrystalline silicon (not shown) is deposited so as to line the walls of each contact hole before the deposition of titanium to act as an anti-leakage barrier. This is followed by deposition of titanium and then tungsten to act as the anti-spiking barrier.

A non-limiting exemplary process 200 to make the structure of FIG. 11 is as follows (doping profiles can be adjusted as appropriate to make normally on or normally off device and to set the pinch off voltage): (step 201) form the double well isolation structure with the multilayer insulation layer 58/60/56 over the whole surface; (step 202) mask and etch the multilayer insulation layer if necessary and implant the channel 102 inside the P-well 32 (typically 1E13 dose at 15 kev followed by 4E11 at 37 KEV with anneal, n-type for an N-channel JFET); (step 203) reform the multilayer insulation layer 58/60/56 over the P-well if it was removed in step 2; (step 204) mask and etch source, drain and gate openings and mask for a gate implant and implant gate region impurities (typically BF2 at 1E15 dosage at approximately 10-15 KEV followed by a second implant at 2E15, 36 KEV); (step 205) remove photoresist and optionally, sputter deposit polycrystalline silicon anti-leakage barrier of about 50 angstroms thickness to line each contact opening; (step 206) mask and develop photoresist to expose source and drain openings and implant source and drain regions (typically arsenic or phosphorus at 1E15 at 10-15 KEV followed by 2E15, 36 KEV to establish junction depths of 20-40 nanometers); (step 207) remove all photoresist, deposit titanium over the entire surface (typically 200 angstroms thick) and bake to form titanium silicide ohmic contacts at the bottoms of the contact holes, then dip off titanium not converted to silicide; (step 208) deposit about 200 angstroms of titanium followed by deposition of a barrier layer of tungsten; (step 209) deposit aluminum and polish back all metal so as to be flush with the top of the CVD oxide layer 56 (which optionally can have a top surface of nitride formed thereon).

In the alternative embodiments described herein and the embodiments of FIG. 8 and FIG. 11 in particular, the insulation layer over the P-well and between the P-well contact 34 and the N-well contact 26 need not be the three layer sandwich, and in particular need not be a three-layer sandwich comprised of thermal oxide 58, silicon nitride 60 and CVD oxide 56. However, this structure is preferred if the source, gate, or drain electrodes are to be extended outside the active area to other active areas to make contact with electrodes of other transistors. The reason for this is that the nitride layer 60 acts as an etch stop to stop the etch through the CVD silicon dioxide layer 60 in the locations where the interconnect channels are being etched. In other words, any of the contact openings for the source, drain and gate contacts over one active area may be extended as an interconnect trench from one active area to another active area by masking the etch to form the contact opening so as to join the contact openings over each active area with an interconnect trench which has nitride layer 60 as its bottom. Then when polycrystalline silicon or metal is deposited to form the source, drain and gate electrodes, it also fills the interconnect trenches and forms an interconnect line. Silicide may be formed on top of the polycrystalline silicon to short out any unintended PN diodes in the interconnect and to increase its connectivity. Chemical mechanical polishing (CMP) to remove the excess polycrystalline silicon or metal leaves the interconnect conductor flush with the top surface of the CVD oxide layer 56 as are the tops of the source, gate and drain contacts. The result is the exemplary non-limiting embodiment of the structure shown in FIG. 12.

FIG. 12 is a cross-sectional view through an interconnect structure which is applicable to the various embodiments disclosed herein. The interconnect shown in FIG. 12 is intended to be the drain-to-drain interconnection shown in FIG. 9 to connect the drain 63 of P-channel JFET FT1 to the drain 65 of N-channel JFET FT2. FT2 has a P-well 120, an N-well 122 which encompasses the P-well and a drain region 124. The P channel JFET FT1 has a N-well 126, a P-well 128 and a drain region 130. The interconnect structure 132 extends the N+ polycrystalline silicon of the drain electrode 65 to meet the P+ polycrystalline silicon of the drain electrode 63 through an interconnect channel etched in the three layer insulation comprised of thermally grown silicon dioxide 58, silicon nitride etch stop layer 60 and CVD silicon dioxide 56. The interconnect channel is a channel etched down through the CVD oxide 56 to the nitride layer 60 and joins the active area defined by P-well 120 to the active area defined by N-well 126. The nitride layer 60 and the thermal oxide layer 58 replace the STI or field oxide in insulating the interconnect 132 from the substrate so that it does not short out the PN junctions between the P-well and the N-well at either active area and is insulated from any voltage applied to the P-substrate 10. Silicide layer 134 shorts out the PN junction 136 within the interconnect 132 and reduces its resistivity to make it a better conductor.

In other embodiments, the insulating layer formed on top of the substrate may be a different combination of materials or all one material, and the interconnect trench may be etched separately from the contact openings. The interconnect trench etch should be such that the interconnect trench does not go all the way down through the insulation layer to the surface of the semiconductor layer of the substrate.

Exemplary Process Of Manufacture of the Active Area Isolation Structure (AAIS)

A non-limiting example of a process 300 for making or forming an active area isolation structure according to an embodiment of the invention is now described with reference to the drawings.

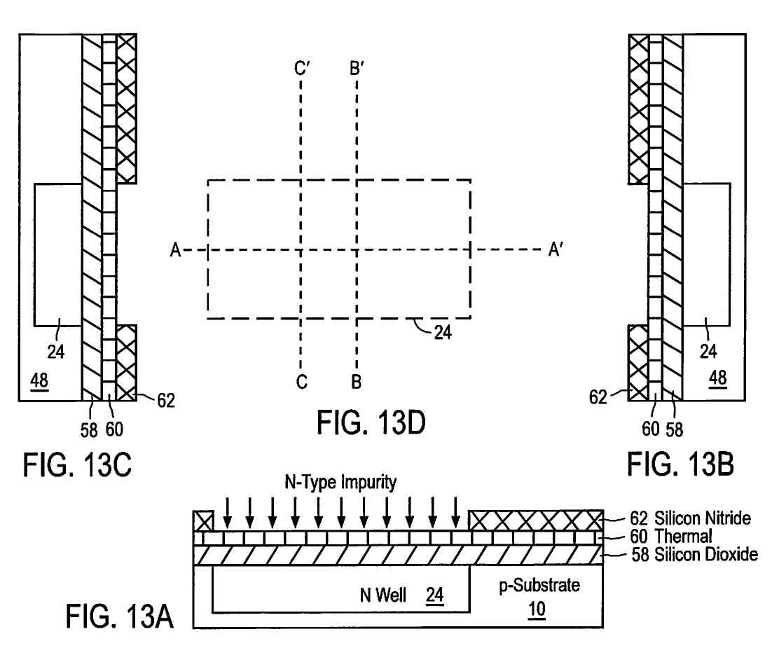

An exemplary embodiment of a process 300 of manufacture of the generic isolation structure shown in FIG. 7 is summarized in below relative to FIGS. 13-15. Recall that this active area isolation structure does not have or involve Shallow Trench Isolation (STI) structural components and may be referred to herein as the non-STI isolation structure. This new non-STI isolation structure formation process exposes an active area 72 inside a P-well within an N-well of the substrate where any MOS or JFET transistor structure may be formed. FIG. 13A is a diagrammatic illustration showing a cross-sectional view through plane A-A′ of FIG. 13D. FIG. 13B is a diagrammatic illustration showing a cross-sectional view through plane B-B′ of FIG. 13D, and FIG. 13C is a diagrammatic illustration showing a cross-sectional view through plane C-C′ of FIG. 13D. The region of N-well 24 and P-doped substrate 10 are indicated by a dashed boxes in FIG. 13D. FIGS. 14A-14D and FIGS. 5A-15D show analogous cross sections to those shown in FIGS. 3A-13D through the device at different stages in the process.

The process 300 will be described starting with FIGS. 13A through 13D which are a cross-sectional views through different planes (A-A′, B-B′, C-C′, and D-D′) of the device after the first few steps to form the N-well implant 24.

With reference to FIGS. 13A-13D, the process begins (step 301) with a substrate 10, 48, such as for example a silicon, germanium, silicon-carbide and silicon-germanium-carbon alloy semiconductor substrate. In the non-limiting embodiment described here, the substrate is a P-doped semiconductor, such as P-doped silicon. In one non-limiting embodiment, the substrate is a <100> crystal oriented silicon substrate doped P-, but other P-doped substrates may be used. Next (step 302), a layer of silicon dioxide 58 (herein after oxide) is thermally grown to a depth of about 100 Å, and then a layer of silicon nitride 60 (hereinafter nitride) is deposited to a depth of about 200 Å on top of the silicon dioxide layer 58 (step 303). A photoresist mask, such as a step mask 62, is formed to mask off the area where an N-type well 24 is to be implanted and exposed for the N-well 24 in the P-doped substrate 10 (step 304), and the substrate is implanted with an N-type impurity (step 305) through the silicon nitride 60 and silicon oxide 58 layers to form the N-well 24. The N-well 24 isolates the JFET constructed therein from surrounding structures. In one non-limiting embodiment, the N-well Implant energy is approximately 50 KEV with an N-type impurity dose of 5E11. An N-well drive-in (step 105) at 950 degrees C. is then performed (step 306). Multiple implants at different energies may be performed and are advantageous for obtaining a better distribution of conductivity enhancing impurities that a single implant.

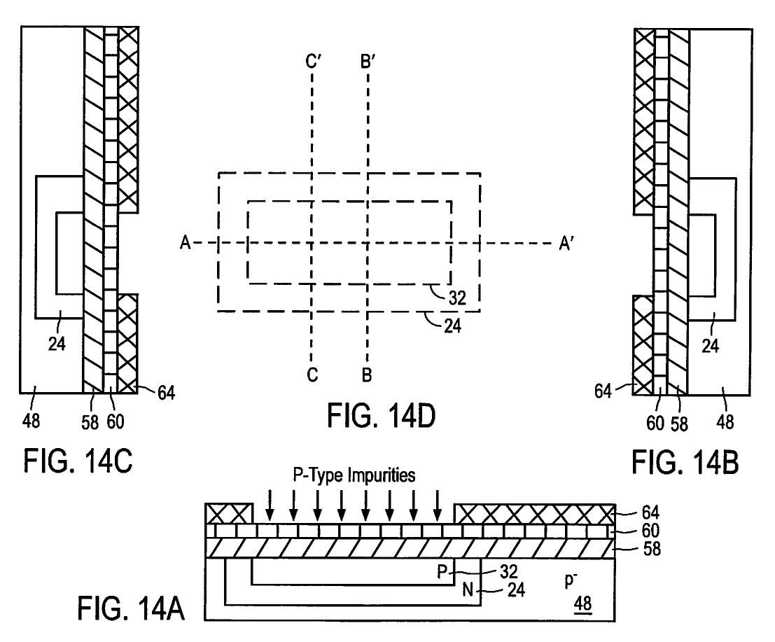

FIGS. 14A through 14D are views including a cross-section through the active area 32 (the P-well of FIG. 14A) of and cross sections along section line B-B′ (FIG. 14B) and section line C-C′ (FIG. 14C) after the first few steps to form the N-well implant and the P-well implant. FIG. 14D is a plan view of the structure showing where the section lines B-B′ and C-C′ occur. With reference to FIGS. 14A-14D, the previously formed step mask 62 is removed (step 307), and a new photoresist mask 64 is formed (step 308) to expose an area where P-well 32 is to be formed (step 309). A P-type impurity implant is then performed (step 310) to form P-well 32 inside N-well 24 through silicon nitride and silicon oxide layers 60, 58. In one non-limiting embodiment, the P-type impurities implant energy is less than approximately 50 KEV with a dose of 5E11 so that P-well 32 is encompassed or contained entirely within N-well 24. In one embodiment, a P-well drive-in at 950 degrees C. is then performed (step 311). Multiple implants at different energies are advantageous and are preferred for best distribution of conductivity enhancing impurities.

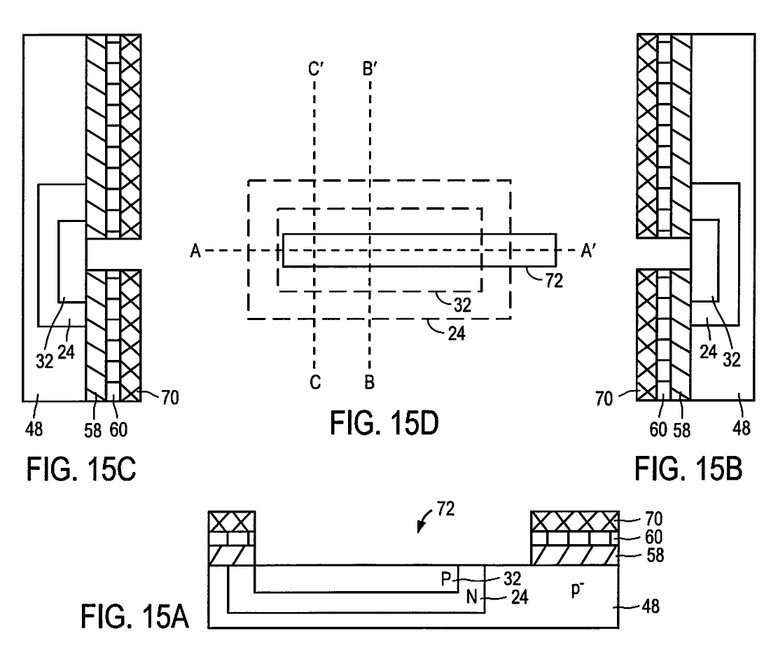

FIGS. 15A through 15D are views including a cross-section through the active area (FIG. 15A) of and cross sections along section line B-B′ (FIG. 15B) and section line C-C′ (FIG. 15C) of JFET isolation structure without STI isolation after the first few steps to form the N-well implant and the P-well implant. FIG. 15D is a plan view of the structure. With reference to FIGS. 15A-15D, the process continues by removing the previous step mask 64 (step 312), and forming new mask 70 (step 313) to expose surface of substrate (in one embodiment the nitride layer 60 and the oxide layer 58) to define (step 314) the location and size of the active area 72 where any transistor device, such as for example any MOS or JFET transistor structure may be formed. After this masking step, the silicon nitride layer 60 and silicon dioxide layer 58 are etched (step 315) down to the upper surface of substrate 48. A plasma etch may advantageously be used which is set up to detect the presence of silicon atoms in the gases produced by the etching process so as to permit control and stopping of the etching when the upper surface of the substrate 48 is reached. Any way of etching through the nitride and oxide layers and stopping at the surface of the substrate will suffice to practice most embodiments. These steps result in exposing an active area inside the P-well where any MOS or JFET transistor structure may be formed. Recall that this non-STI isolation structure is show in and described with respect to FIG. 7.

The forming of the active area isolation structure is now complete and processing to form or manufacture whatever semiconductor or transistor device desired, such as for example a JFET or MOS device, in the active area (as described elsewhere herein) may begin.

This concludes the illustrative discussion of the use of the Non-STI isolation structure for the JFET device type. The use of the isolation structure for other exemplary transistors, including for MOS transistors will now be presented.

Exemplary MOS Transistor Embodiments

As described above, any JFET, MOS, IGFET or other transistor structure can be built in the active area 31 of the isolation structure show in FIG. 7. One such transistor structure is an NMOS type MOS transistor structure depicted in FIG. 16. The reverse-biased PN junction active area isolation structure in the NMOS structure of FIG. 16 is the same structure as is shown in FIG. 7. The MOS transistor selected for this example is an N-channel device or an NMOS transistor. The MOS transistor may alternatively be a P-channel device or PMOS transistor, or other MOS transistor.

In this non-limiting embodiment, the NMOS transistor includes the following elements, layers, regions, and the like as shown in the drawing: thermal gate oxide 80, a polysilicon gate contact 82 which can be doped either N+ or P+ (because it only needs to be conductive and does not contact the single crystal semiconductor of the P-well 32), a metal silicide layer 84 that reduces the resistivity of the gate surface contact, an N+ implanted link region 86 between the gate and source and an N+ implanted link region 88 between the gate and drain, an N+ doped polysilicon source surface contact 92, an N+ doped source region 90 (which can be implanted or thermally driven in from the N+ doped polysilicon source surface contact 92 which overlies it and is in electrical contact therewith), a layer of metal silicide 94 on the top surface of the source surface contact 92 and which reduces the resistivity thereof, an N+ doped polysilicon drain surface contact 98, an N+ doped drain region 96 (which can be implanted or thermally driven in from the N+ doped polysilicon drain surface contact 98 which overlies it and is in electrical contact therewith), and a metal silicide layer 100 on top of the drain polysilicon surface contact which reduces the resistivity thereof. It will be appreciated that all polarities can be reversed for a PMOS transistor relative to the polarities described relative to the NMOS transistor.

An example process 400 to make the NMOS transistor of FIG. 16 is now described. This particular non-limiting embodiment has polysilicon source, drain, and gate surface contacts in the active area of a reverse-biased junction isolated isolation structure.

A junction isolated isolation structure is formed (step 401), such as the non-STI isolation structure of FIG. 7, having an open active area 72 over P-well 32.

Conventional threshold adjustment ion implantations (not shown) may then be performed (step 402) in regions of active areas 72 where channels are to be formed to change doping to adjust threshold voltage.

A thin layer of gate insulator 80 may then be grown (step 403), such as by thermally growing, to a thickness of about 10 to 25 Angstroms depending upon design rules. For example, for the thickness may be in the range of 6 to 25 Angstroms for 45-90 nanometer design rules, between about 10-12 Angstroms for 45 nanometer design rules, and somewhat less for 32 nanometer or smaller design rules. The thin layer of gate insulator may advantageously be a thin layer of thermally grown silicon dioxide, or other insulator.

The structure may then be masked (step 404) and etched (step 405) to remove gate insulator from an area of the surface of the substrate 10, 48 in the active area where source and drain polycrystalline surface contacts will make contact with the silicon. The silicon with which contact may be made may be single crystal silicon.

A chemical vapor deposition (CVD) process is used to deposit a layer of polycrystalline silicon (polysilicon) over the entire wafer (step 406). In one non-limiting embodiment, this polysilicon layer may deposited to a thickness of about 500 Angstroms, though other thicknesses may be utilized, including for example other thickness that are thinner or advantageously substantially thinner than the thickness of the polysilicon in the conventional MOS or CMOS process may also be used. The thinner thickness provide more of the advantages described elsewhere in the application.

A thin layer of Silicon Nitride is optionally but advantageously deposited (step 407), such as by chemical vapor deposition (CVD) on top of the polycrystalline silicon layer to act as a polish stop. Typical thickness of this silicon nitride layer is about 200 Angstroms, but any thickness that will function to act as an effective polish stop can be used.

A photoresist layer is deposited (step 408), masked (step 409), and developed (step 410) to expose photolithographically defined regions of the silicon nitride and underlying polycrystalline silicon to be removed to define separate source, drain, and gate surface contacts for the NMOS device.

It may be appreciated in light of the description provided here, that the size of the gaps between the gate surface contact and the source and drain surface contacts is determined photo-lithographically and can be the minimum design rule line width which can be smaller than a conventional spacer. In some embodiments however, a MOS structure is built in the active area consisting of a gate surface contact, gate oxide, spacers comprised of silicon dioxide and silicon nitride insulating the vertical walls of the gate surface contact formed by an anisotropic etch, self-aligned metal silicide surface contacts for implanted source and drain regions, and possibly optional implanted link regions under the spacer to couple the source and drain implants to the channel region.

The silicon nitride layer is etched away in the exposed areas (step 411). Following the silicon nitride etch, the Polycrystalline Silicon layer is etched (step 412) to define an isolated gate surface contact 82, source surface contact 92, and drain surface contact 98 for the NMOS device. Typical gap distance in the new CMOS process devices between the gate surface contact and source and drain contacts is between about 40 to 45 NM depending upon the design rules, and that gap distance will continue to shrink as equipment and processes improve and device dimensions are further scaled downward.

A link region is implanted (step 413) by performing a link implant using ion implantation of N-type impurities to heavily dope the link areas 86 and 88 (See FIG. 16) between the gate and the source and drain of the NMOS device to increase its conductivity. Typical dosages are 1013 to 1014 impurity atoms per cubic centimeter with an implant energy that is typically less than 10 KEV. These link implants should advantageously be as shallow as possible to help minimize any short channel leakage current.

A silicon dioxide layer 102 is deposited over the entire wafer (step 414), such as by CVD, of sufficient thickness to fill the gaps between the surface contacts.

The Silicon Dioxide layer 102 is polished back (step 415), such as by using Chemical Mechanical Polishing (CMP) back, to a state where the silicon dioxide layer top surface ## is flush with the top surface of the silicon nitride caps covering the top of each surface contact so as to form a planar surface.

The Silicon Nitride caps on each polycrystalline silicon surface contact are then removed (step 416).

Photoresist material is deposited (step 417), masked (step 418), and developed (step 419) to cover the surface contacts of the isolation structure but to expose the NMOS gate surface contact 82, the source surface contact 92, and drain surface contact 98.

In one embodiment, an ion implantation process (step 420) to implant an N-type conductivity enhancing impurity (such as for example of Arsenic) is performed to dope NMOS source 92, drain 98, and gate 82 surface contacts to be N-type contacts. The silicon dioxide 102 between the gate surface contact 82 and the substrate advantageously prevents a undesired diode from being unintentionally formed so the gate surface contact 82 can be doped N-type at the same time and using the same implant mask which is used to dope the source contact 92 and the drain contact 98 of the NMOS device.

In another embodiment, separate implant masks are used to implant the source and drain contacts and gate surface contact of each NMOS transistor separately using opposite conduction type impurities. The gate contact of the NMOS device can be doped with the same impurity type as the source and drain contacts of the NMOS device (N+) or it can be doped the opposite polarity (P+) since no diode is formed between the gate contact and the substrate and no gate current flows. It is only necessary to make the gate contact conductive and conductivity may be achieved using either dopant type. The separate implants of the source and drain surface contacts from the gate surface has the advantageous feature that the doping profile of the source and drain regions under the source and drain contacts may be controlled to achieve desired transistor characteristics by controlling the doping profile of these regions (for example, the junction depth, the impurity concentration, the impurity distribution throughout the regions, and/or other profiles and characteristics).

An anneal step and thermal drive-in step (step 421) may be performed (separately or as a combined step) to cause impurities from overlying Polycrystalline Silicon source and drain contacts to diffuse into the underlying substrate to form self-aligned source and drain regions 90 and 96. In the NMOS device, the source region is 90 and the drain regions is 96 with link regions 86 and 88 coupling these regions to the channel region under the gate oxide.

This anneal also anneals implanted impurities in Polycrystalline Silicon. Typical temperatures may usually range from 900-1200 degrees C. for an interval from about 5 seconds to 1 millisecond, and of course for any time between these when appropriate or convenient. This short anneal time forms very shallow source and drain regions thereby reducing short channel leakage and reducing power consumption. Usually, there is no need for a deeper source and drain region because no suicide is being formed on the surface of the substrate. It may be appreciated in light of the description provided here that the doped polysilicon surface contacts may be extended outside the active area in order to make contact with other device terminals formed on the same wafer so as to form polysilicon level interconnections.

A suicide layer is formed (step 422) on top of all polycrystalline silicon surface contacts by depositing Titanium, Cobalt, Nickel or other suitable metal or other material and heating (step 423) the structure to about 600 degrees C. for a short time, and then dipping off the metal (step 424) which has not been converted to silicide.

An insulation layer is deposited, contact holes formed therein, and metal is deposited and etched to form interconnects (step 425) as is known in the art and not described in further detail herein.

Exemplary MOS Transistor with Silicide Source and Drain Surface Contacts and a Polysilicon Gate Surface Contact in a Reverse Biased PN Junction Isolation Structure with No Spacers

Attention is now direction to an alternative device structure in which a MOS transistor with silicide source and drain surface contacts and a polysilicon gate surface contact is formed in the reverse biased PN junction AAIS with no spacers.

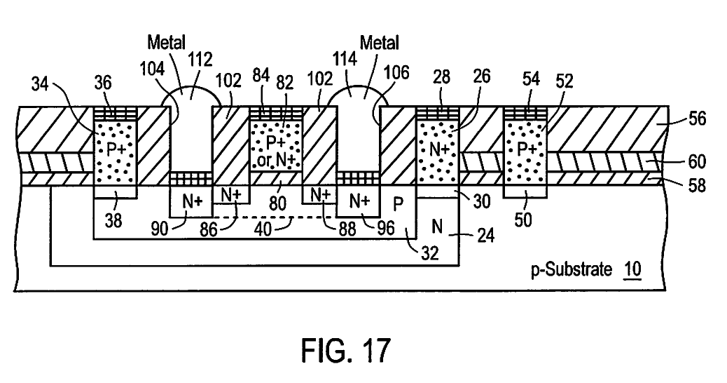

FIG. 17 is a cross-section through the active area of another embodiment for an MOS transistor fabricated in a non-STI, reverse biased PN-junction AAIS isolation structure using a polysilicon gate surface contact with no spacers and silicide source and drain surface contacts. This embodiment features photolithographically determined gaps between the gate surface contact and the source and drain silicide contacts since the conventional anisotropically formed spacers are not formed. All structures having the same reference numbers as in FIG. 16 not specifically discussed here are the same structure formed in the same way. The new structures that are present in this embodiment are: (1) source and drain regions 90 and 96 which are formed by ion implantation through contact holes 104 and 106 formed in CVD silicon dioxide layer 102; (2) metal silicide layers 108 and 110 formed at the surface of the source and drain regions 90 and 96 and at the bottom of the contact holes; and (3) metal contacts 112 and 114 to the silicide layers 108 and 110. The implanted source and drain regions are implanted through contact holes 104 and 106 using the same etch mask as was used to etch these contact holes. Metal silicide layers 108 and 110 are formed on the surface of the source and drain regions in conventional manner as is formation of the metal contacts 112 and 114.

An example process 500 to make the MOS transistor structure of FIG. 17 with silicide source and drain surface contacts and a polysilicon gate surface contact is formed in the reverse biased pn junction AAIS with no spacers is now described. Although the particular combination of process steps is novel and results in the novel MOS transistor structure, at least some of the individual process steps are themselves known in the art and not described in great detail to avoid obscuring the inventive steps alone and in combination with the other steps.

(1) Start from or form the Non-STI, reverse biased PN junction AAIS isolation structure of FIG. 7 (step 301);

(2) Threshold adjustment implant in active area (step 502);

(3) Thermally grow gate oxide over active area (step 503);

(4) Mask and etch to remove gate oxide at locations where source and drain are to be formed and, optionally, at locations where link implants are to be formed (step 504);

(5) CVD deposition of polysilicon layer over active area, typically about 500 angstroms or less thick (step 505);

(6) Deposit silicon nitride on top of the polysilicon layer (step 506);

(7) Mask and etch silicon nitride layer and polysilicon layer to form a gate surface contact and expose the surface of the active area outside the perimeter of the gate surface contact (step 507);

(8) Mask and do a link implant to form the link regions (step 508);

(9) Deposit CVD silicon dioxide layer 102 over wafer of sufficient thickness to cover gate surface contact (step 509);

(10) Polish CVD silicon dioxide back to flush with top surface of the silicon nitride layer (step 510);

(11) Mask and etch contact holes 104 and 106 in CVD oxide layer 102 (step 511);

(12) Remove silicon nitride (step 512);

(13) Mask and implant polysilicon gate surface contact 82 and source and drain regions 90 and 96 N+ (step 513);

(14) Anneal implanted impurities (step 514);

(15) Form metal silicide at bottom of contact holes for source and drain and on top of polysilicon gate surface contact (step 515); and

(16) Form metal contacts to source and drain silicide layers and gate surface contact silicide layer and to the silicide layers on top of the P-well, N-well and substrate surface contacts 34, 26 and 52 (step 516). Typically this is done by depositing a layer of CVD oxide over the entire wafer, etching contact holes therein down to the silicide of each surface contact, and depositing a layer of metal so as to fill the contact holes and then etching the metal to form desired interconnects.

Embodiment of CMOS Structure With Spacers Formed in Active Area Isolation Structure

Attention is now direction to another alternative device structure in which a CMOS transistor with polysilicon gate surface contact having a silicide cap and a spacer dielectric insulating the vertical side walls of the gate surface contact is formed in the reverse biased PN junction AAIS with spacers.

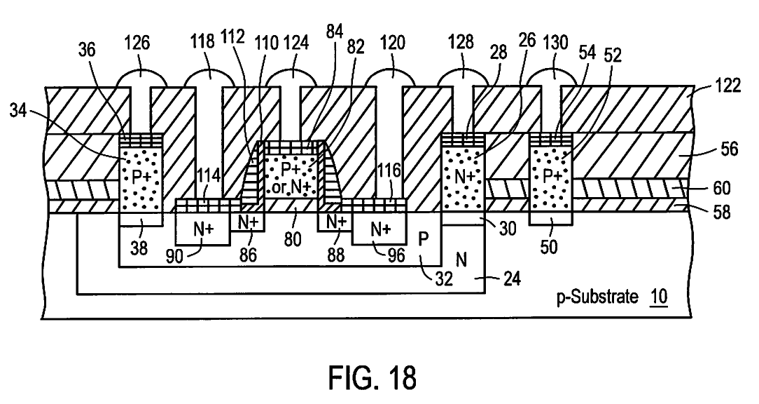

FIG. 18 is a cross sectional view through another alternative embodiment of an MOS transistor embodiment which can be made in the active area of the non-STI isolation structure of FIG. 7. This particular non-limiting example uses a polysilicon gate surface contact 82 having a silicide cap 84 and a spacer dielectric insulating the vertical side walls of the gate surface contact 82.]

The dielectric structure is comprised of a silicon dioxide layer 110 and a silicon nitride layer 112. The spacer is formed after the link implants 86 and 88 are implanted, and before metal silicide contacts 114 and 116 for the source region 90 and drain region 96, respectively, are formed. The source region metal silicide contact 114 and the drain region metal silicate contact 116 are therefore self aligned to the edge of the dielectric spacers. Contact to the source and drain regions is made using metal contacts 118 and 120 formed in contact holes in a layer of dielectric 122 deposited on the wafer after the link implants and spacer dielectric structures and the silicide layers 114 and 116 have been formed. Contact to the gate surface contact silicide layer is made through a metal contact 124 formed in a contact hole in dielectric layer 122. Metal contacts 126, 128 and 130 are also formed in contact holes etched in dielectric layer 122 to provide electrical connections to the P-well contact 34, the N-well contact 26 and the substrate contact 52, respectively. This same sort of contact structure with metal contacts formed in contact holes through a dielectric layer formed over the entire wafer may also be used in the embodiment of FIG. 17.

An example process 600 to make the CMOS transistor with polysilicon gate surface contact having a silicide cap and a spacer dielectric insulating the vertical side walls of the gate surface contact of FIG. 18 is now described. Although the particular combination of process steps is novel and results in the novel CMOS transistor structure, at least some of the individual process steps are themselves known in the art and not described in great detail to avoid obscuring the inventive steps alone and in combination with the other steps.

(1) Start from or form the Non-STI, reverse biased PN junction AAIS isolation structure of FIG. 7 (step 601);

(2) Threshold adjustment implant in active area (step 602);

(3) Thermally grow gate oxide over active area (step 603);

(4) Mask and etch to remove gate oxide at locations where source and drain are to be formed and, optionally, at locations where link implants are to be formed (step 604);

(5) CVD deposition of polysilicon layer over active area, typically about 500 angstroms or less thick (step 605);

(6) Deposit silicon nitride on top of the polysilicon layer (step 606);

(7) Mask and etch silicon nitride layer and polysilicon layer to form a gate surface contact and expose the surface of the active area outside the perimeter of the gate surface contact (step 607);

(8) Mask and do a link implant to form the link regions (step 608);

(9) Deposit a conventional thin layer of CVD silicon dioxide suitable as the first layer of a spacer dielectric (step 609);

(10) Deposit a conventional thin layer of silicon nitride over the layer of silicon dioxide, the silicon nitride layer being suitable to form a dielectric spacer (step 610);

(11) Do an anisotropic etch to remove horizontal components of the silicon dioxide and silicon nitride layers and leave spacer dielectric structures protecting the vertical sidewalls of the gate surface contact (step 611);

(12) Mask to expose portions of active area where source and drain implants are to be formed (step 612);

(13) Remove nitride cap on polysilicon gate surface contact (step 613);

(14) Mask to expose active area portions where source and drain regions are to be formed and to expose top of polysilicon gate surface contact and implant source and drain regions and polysilicon gate surface contact with N-type impurities to N+ conductivity

(step 614);

(15) Deposit refractory metal over the wafer and do high temperature bake to anneal implanted impurities and form silicide (typically 600 degrees C. for a time sufficient to form the silicide and anneal the impurities) (step 615);

(16) Deposit CVD silicon dioxide layer 122 over wafer of sufficient thickness to cover gate surface contact (step 616);

(17) Polish CVD silicon dioxide back to flush with top surface of the silicon nitride layer (step 617);

(18) Mask and etch contact holes in CVD oxide layer to the silicide layers over the source and drain regions, over the gate surface contact and over the P-well, N-well and substrate polysilicon surface contacts (step 618); and

(19) Form metal contacts to source and drain silicide layers and gate surface contact silicide layer and to the silicide layers on top of the P-well, N-well and substrate surface contacts 34, 26 and 52 (step 619). Typically this is done by depositing a layer of metal so as to fill the contact holes and then etching the metal to form desired interconnects.

Although the various processes have been described in terms of a number of steps, it may be appreciated that steps may be combined and performed as a single step or performed in a different order if the process and resulting structure being formed provide for such change in order. It may also be appreciated in light of the description provided herein that a number of detailed steps may be combined or performed together to accomplish an over all result, so that for example, the formation of a semiconductor device according to embodiments of the invention may take a different number of steps than enumerated in the detailed description provided herein.

Furthermore, although the invention has been described in terms of the various examples and embodiments disclosed herein, those skilled in the art may appreciate other embodiments that are still within the scope and spirit of the invention. All such embodiments are intended to be included within the scope of the claims appended hereto.

I/We claim:

1. A device comprising:
a semiconductor substrate doped to a first conductivity type;
a first well formed within said substrate and doped to a second conductivity type;
a second well formed within said first well and doped to a first conductivity type, said second well defining an active area; and
separate electrically conductive surface contacts including a first electrical contact to said first well, a second electrical contact said second well, and a third electrical contact to said substrate, such that predetermined voltages can be applied to the contact of the first well and to the contact of the second well so that a junction between the first and second wells forms a reverse-biased diode, thereby electrically isolating the second well from the first well and the substrate.

2. A device as in claim 1, wherein the first well of a second conductivity type is implanted in said substrate.

3. A device as in claim 1, wherein the semiconductor has an insulating layer on top of a surface thereof.

4. A device as in claim 3, wherein said insulating layer on top of a surface of the substrate comprises:
a layer of silicon dioxide covering the top surface of said semiconductor substrate; and
a layer of silicon nitride covering said layer of silicon dioxide.

5. A device as in claim 4, further comprising:
a plurality of contact holes etched in said layers of silicon dioxide and silicon nitride to expose regions on the top surface of said substrate where the electrical contact may be made to the substrate, said first well, and said second well, respectively;
a surface contact in each said contact hole making electrical contact to each of said substrate, said first well, and said second well.

6. A device as in claim 1, further comprising a transistor formed in said active area.

7. A device as in claim 6, wherein the transistor formed in said active area comprises at least one of a JFET transistor, a MOS transistor, a CMOS transistor, an NMOS transistor, PMOS transistor, N-channel Junction Field Effect Transistor, a P-channel Junction Field Effect Transistor, and an IGFET.

8. A device as in claim 1, wherein semiconductor substrate comprises a material selected from a group consisting of silicon, gallium arsenide, germanium, silicon carbide, silicon-germanium-carbon alloy, and alloys thereof.

9. A device as in claim 1, wherein said first and second wells are formed in epitaxially deposited semiconductor formed on an insulating substrate.

10. A device as in claim 1, wherein:
said substrate is doped P-;
said first well is doped N-type; and
said second well is doped P-type.

11. A device as in claim 1, wherein each said surface contact comprises polycrystalline silicon doped with a conductivity enhancing impurity of the same conductivity type as the structure with which said contact means makes electrical contact and a layer of metal silicide on a top surface of said surface contact.

12. A device as in claim 11, wherein the top surface of said doped polysilicon surface contact is flush with surrounding insulating material of said multi-layer insulation layer so as to form a flat surface upon which additional insulating material and metal interconnect layers may be formed.

13. A device as in claim 6, wherein said transistor formed in said active area includes a junction field effect transistor (JFET) comprising:
non-overlapping source and drain regions formed in said second well so as to be adjacent to a top surface of said second well and doped with conductivity enhancing impurities of said second conductivity type;
an electrically conductive gate electrode overlying said second well between said source and drain regions;
a gate region of said first conductivity type and formed in said second well and adjacent said surface of said second well between said source and drain regions;
electrically conductive source and drain electrodes formed on top of said second well and overlying said source and drain regions, respectively so as to make electrical contact therewith; and
a channel region of said second conductivity type formed in said second well region immediately underneath said gab region and between said source and drain regions.

14. A device as in claim 13, wherein said gate electrode is polycrystalline silicon doped to a first conductivity type, and wherein said gate region received its first conductivity type impurities by diffusion from said overlying gate electrode so as to be self-aligned with said gate electrode.

15. A device as in claim 13, wherein said gate region received its first conductivity type impurities via one or more ion implantation steps.

16. A device as in claim 13, wherein the doping profile of said gate and channel regions are such that said junction field effect transistor is off when the gate-to-source voltage is substantially 0.0 volts.

17. A device as in claim 13, wherein said gate and source and drain electrodes are doped polycrystalline silicon.

18. A device as in claim 13, wherein said gate and source and drain electrodes are polycrystalline silicon which are doped to the proper conductivity types by one or more steps of ion implantation.

19. A device as in claim 13, wherein said gate and source and drain electrodes are polycrystalline silicon which are doped to the proper conductivity types by one or more steps of plasma immersion implantation.

20. A device as in claim 13, wherein said gate and source and drain electrodes are metal with suitable metal atom spiking barriers to prevent migration of metal atoms from the electrodes into the underlying semiconductor.

21. A device as in claim 1, wherein said source and drain regions each comprise a first region of impurities that were diffused into said second well from overlying polycrystalline silicon source and drain electrodes respectively and a second region of impurities which were implanted into said second well between said first region and said gate region.

22. A device as in claim 6, wherein said transistor formed in said active area includes a junction field effect transistor (JFET) comprising:
non overlapping source and drain regions formed in said second well so as to be adjacent to a top surface of said second well and doped with conductivity enhancing impurities of said second conductivity type;
an epitaxially grown layer of semiconductor formed only over said second well;
an electrically conductive gate electrode overlying said second well between said source and drain regions and over said epitaxially grown layer of silicon-germanium;
a gate region of said first conductivity type and formed in said epitaxially grown layer of silicon-germanium under said gate electrode and between said source and drain regions;
electrically conductive source and drain electrodes formed on top of said epitaxially grown layer of silicon-germanium and overlying said source and drain regions, respectively so as to make electrical contact therewith through said epitaxially grown layer of silicon-germanium; and
a channel region of said second conductivity type formed in said epitaxially grown layer of silicon-germanium and immediately underneath said gate region and between said source and drain regions.

23. A device as in claim 22, wherein said epitaxially grown layer of semiconductor is a silicon-germanium alloy.

24. A device as in claim 22, wherein said epitaxially grown layer of semiconductor is a strained silicon germanium alloy.

25. A device as in claim 22, wherein said epitaxially grown layer of semiconductor is a silicon-germanium-carbon alloy.

26. A device as in claim 22, wherein said gate electrode is silicon carbide or silicon-germanium carbide and said epitaxially grown layer of semiconductor is silicon-germanium alloy or strained silicon-germanium alloy or silicon-germanium-carbon.

27. A device as in claim 6, wherein said transistor formed in said active area is a junction field effect transistor (JFET) comprising:
non overlapping source and drain regions formed in said second well so as to be adjacent to a top surface of said second well and doped with conductivity enhancing impurities of said second conductivity type;
a dielectric layer formed over said second well and having openings formed therein for source, gate and drain electrodes;
a gate region of said first conductivity type and formed in said second well and adjacent said surface of said second well between said source and drain regions;
a metal gate electrode formed in said gate electrode opening of said dielectric layer so as to lie over said gate region, and having an ohmic contact to said gate;
metal source and drain electrodes formed in said source and drain electrode openings of said dielectric layer and on top of said second well and overlying said source and drain regions, respectively so as to make electrical contact therewith via ohmic contacts; and
a channel region of said second conductivity type formed in said second well region immediately underneath said gate region and between said source and drain regions.

28. A device as in claim 27, wherein each of said metal gate, source and drain electrodes is formed of aluminum and each has a titanium and tungsten anti-spiking barrier between said aluminum and the underlying gate, source and drain regions, respectively.

29. A device as in claim 27, further comprising a polycrystalline silicon anti-leakage barrier lining each of said source, gate, and drain electrode openings of said dielectric layer

30. A device as in claim 1, wherein each said surface contact is comprised of polysilicon doped to the same conductivity type as the underlying structure to which said surface contact makes electrical contact, and having metal silicide formed on top of said polysilicon surface contact.

31. A device as in claim 1, wherein each said surface contact is comprised of a layer of metal silicide.

32. A process to make a semiconductor device, the process comprising:
A) growing an insulator layer on top of a substrate having a semiconductor layer which is doped to a first conductivity type;
B) masking to expose a first area where a first well of a second conductivity type is to be formed and implanting second conductivity type impurities into said semiconductor layer to form a first well;
C) masking to expose a second area where a second well of a first conductivity type is to be formed and implanting first conductivity type impurities to form a second well inside said first well;
D) masking to define an active area and etching through said insulating layer to expose the top surface of said semiconductor layer;
E) forming contact holes in said insulating layer to expose portions of the top surface of said substrate where electrical contact may be made to said substrate, said first well and said second well, and forming an opening in said insulating layer to expose an active area; and
F) forming surface contacts in said contact holes making electrical contact with said substrate, said first well and said second well.

33. A process as in claim 32, wherein the growing of the insulator comprises thermally growing a silicon dioxide layer on top of the substrate and depositing a layer of silicon nitride on the silicon dioxide layer.

34. A process as in claim 32, wherein:
the growing of the insulator layer comprises thermally growing the insulator layer; and
the insulator layer comprises a oxide layer.

35. A process as in claim 32, wherein:
the insulator layer comprises a silicon dioxide oxide layer, and further comprises a layer of silicon nitride deposited or formed on said silicon dioxide layer.

36. A process as in claim 32, wherein:
the substrate has at least a single crystal semiconductor layer.

37. A process as in claim 32, further comprising:
removing the first mask formed prior to the second masking; and
removing the second mask prior to the third masking.

38. A process as in claim 32, wherein said implant energy of the implant to form said first well is substantially 50 KEV and the implant dosage is substantially 5E11, and multiple implants are performed at different energy levels to achieve better impurity distribution and wherein said implant step includes an annealing and thermal drive in step so as to activate the implanted impurities.

39. A process as in claim 32, wherein said implant step of step C is carried out at a peak energy level which is such as to form said second well within the boundaries of said first well; and said implant step includes a high temperature annealing and thermal drive in step to activate the implanted impurities.

40. A process as in claim 32, further comprising steps for forming a transistor structure in said active area.

41. A process as in claim 40, wherein the transistor structure formed in said active area comprises at least one of a JFET transistor, a MOS transistor, a CMOS transistor, an NMOS transistor, PMOS transistor, N-channel Junction Field Effect Transistor, and a P-channel Junction Field Effect Transistor.

42. A process as in claim 32, further comprising the steps:
performing a threshold adjustment implant in said active area;
forming a gate oxide layer over said active area;
masking and etching to remove said gate oxide layer at locations where source and drain regions are to be formed and, optionally, at locations where link implants are to be formed;
forming a polysilicon layer over active area;
forming a layer of silicon nitride on top of the polysilicon layer;
masking and etching said silicon nitride layer and polysilicon layer to form gate, source and drain surface contacts separated by gaps the size of which is determined photolithographically;
forming link regions in said substrate below gaps between said source and drain surface contacts and said gate surface contact;
forming a silicon dioxide layer over said active area of sufficient thickness to cover all said surface contacts;
polishing said silicon dioxide layer back to flush with top surface of the silicon nitride layer;
masking and implanting said source, drain and gate surface contacts with suitable conductivity enhancing impurities;
performing a high temperature bake to anneal the implanted impurities and thermally drive impurities from said source and drain surface contacts into the underlying substrate to form source and drain regions;
removing said silicon nitride; and
forming silicide on the top surfaces of said polysilicon source, drain and gate contacts.

43. A process as in claim 32, further comprising the steps:
performing a threshold adjustment implant in said active area;
forming a gate oxide layer over said active area;
masking and etching to remove said gate oxide layer at locations where source and drain regions are to be formed and, optionally, at locations where link implants are to be formed;
forming a polysilicon layer over said active area;
forming a layer of silicon nitride on top of the polysilicon layer;
masking and etching said silicon nitride layer and polysilicon layer to form a gate surface contact;
forming link regions in said substrate;
forming a silicon dioxide layer over said active area of sufficient thickness to cover said gate surface contact;
polishing said silicon dioxide layer back to flush with a top surface of the silicon nitride layer;
forming contact holes in said silicon dioxide layer at locations where said source and drain regions are to be formed in said substrate;
removing said silicon nitride on top of said gate surface contact;
implanting said polysilicon gate surface contact N+ and implanting regions of said substrate exposed by said contact holes N+ to form source and drain regions; and
depositing refractory metal and performing a high temperature bake to anneal the implanted impurities and form metal silicide at the bottom of said contact holes in electrical contact with said source and drain regions and on top of said polysilicon gate surface contact.

44. A process as in claim 32, further comprising the steps:
performing a threshold adjustment implant in said active area;
forming a gate oxide layer over said active area;
masking and etching to remove said gate oxide layer at locations where source and drain regions are to be formed and, optionally, at locations where link implants are to be formed;
forming a polysilicon layer over said active area;
forming a layer of silicon nitride on top of the polysilicon layer;
masking and etching said silicon nitride layer and polysilicon layer to form a gate surface contact;
forming link regions in said substrate;
forming a silicon dioxide layer over said active area of sufficient thickness to form part of a spacer dielectric insulating vertical walls of said gate surface contact;
forming a silicon nitride layer over said silicon dioxide layer of sufficient thickness to form part of a spacer dielectric insulating vertical walls of said gate surface contact;
anisotropically etching said silicon dioxide layer and said silicon nitride layer to form a dielectric spacer insulating sidewalls of said polysilicon gate surface contact;
exposing portions of said active area where source and drain regions are to be formed;
removing said silicon nitride on top of said gate surface contact;
implanting said polysilicon gate surface contact with impurities of a first or second conductivity type and implanting regions of said substrate where source and drain regions are to be formed with impurities of a first conductivity type to form source and drain regions, where first and second conductivity types are N-type and P-type; and
forming silicide in electrical contact with said source and drain regions and on top of said polysilicon gate surface contact.

45. A method for forming an interconnect conductor between nodes in an integrated circuit having no Shallow Trench Isolation (STI) or field oxide between active areas of transistors comprising the steps:
depositing a layer of insulating material on the surface of a semiconductor layer of a substrate, wherein said insulating layer is comprised of a first layer of silicon dioxide, an intermediate layer of silicon nitride, and a top layer of silicon dioxide;
etching a contact opening in said layer of insulating material all the way down to a top surface of said semiconductor layer;
etching at least one interconnect channel down through said top layer of silicon dioxide to a top of said silicon nitride layer, said trench interconnecting with said contact opening;
depositing a layer of titanium or other metal suitable to form a silicide over the entire structure so as to form a lining for said contact opening and said interconnect channel;
baking said structure so as to form a silicide ohmic contact in the bottom of said contact opening;
etching off excess titanium or other suitable metal for forming the silicide which has not formed silicide;
depositing a layer of titanium or other suitable metal so as to line said contact opening and said interconnect channel;
depositing a layer of tungsten or other spiking barrier metal on top of said layer of titanium;
depositing a layer of aluminum so as to fill said contact opening and said interconnect channel; and
polishing said aluminum in said contact opening and said interconnect channel down so as to be flush with said top surface of said top layer of silicon dioxide.

46. A interconnect conductor formed between nodes in an integrated circuit having no Shallow Trench Isolation (STI) or field oxide between active areas of transistors as formed according to the method of claim 45.
